(19) United States
(12) Patent Application Publication
(10) Pub. No.: US 2021/0109136 A1
(43) Pub. Date: Apr. 15, 2021

(54) METHODS TO AUTOMATICALLY ASSOCIATE WIRELESS CURRENT SENSORS WITH VOLTAGES OF A POWER SYSTEM

(71) Applicant: Schweitzer Engineering Laboratories, Inc., Pullman, WA (US)

(72) Inventor: Kei Hao, Anaheim, CA (US)

(73) Assignee: Schweitzer Engineering Laboratories, Inc., Pullman, WA (US)

(21) Appl. No.: 16/708,731

(22) Filed: Dec. 10, 2019

Related U.S. Application Data
(60) Provisional application No. 62/914,329, filed on Oct. 11, 2019.

(51) Int. Cl. G01R 19/25; G01R 15/18

(52) U.S. Cl. CPC G01R 19/2513; G01R 15/18

(57) ABSTRACT

An intelligent electronic device (IED) that associates current measurements from wireless current sensors with voltages of a power line are described. For example, an IED may receive a first current measurement from a first WCS on a first phase of a power line. The IED may receive a first voltage quantity from a voltage sensing device on the first phase of the power line. The IED may determine a phase shift between the first voltage quantity and the first current measurement to use as a reference phase shift. The IED may receive a second current measurement from a second WCS on a second phase of the power line. The IED may associate the second WCS with a second voltage quantity based at least in part on the reference phase shift.

### CROSS-REFERENCE TO RELATED APPLICATION

The present application claims the benefit under 35 U. S.C. § 119(e) of U.S. Provisional Patent Application No. 62/914,329, filed Oct. 11, 2019, entitled “METHODS TO AUTOMATICALLY ASSOCIATE WIRELESS CURRENT SENSORS WITH VOLTAGES OF A POWER SYSTEM,” which is hereby incorporated by reference in its entirety for all purposes.

### TECHNICAL FIELD

The present disclosure relates generally to wireless current sensors and, more particularly, to automatically associating wireless current sensor measurements with voltages of a power system.

### BRIEF DESCRIPTION OF THE DRAWINGS

Non-limiting and non-exhaustive embodiments of the disclosure are described herein, including various embodiments of the disclosure with reference to the figures listed below.

FIG. 1 is a one-line diagram of an electric power delivery system having an intelligent electronic device (IED), in accordance with an embodiment.

FIG. 2 is a block diagram of the IED in a three-phase electric power delivery system of FIG. 1, in accordance with an embodiment.

FIG. 3 is a phasor diagram of the voltage and current of the three-phase electric power delivery system of FIG. 2, in accordance with an embodiment.

FIG. 4 is a block diagram of an example illustrating a first technique for installing wireless current sensors (WCSs) for the IED of FIG. 2, in accordance with an embodiment.

FIG. 5 is a block diagram of an example illustrating a second technique for installing WCSs for the IED of FIG. 2, in accordance with an embodiment.

FIG. 6 is a block diagram of an example illustrating a third technique for installing WCSs for the IED of FIG. 2, in accordance with an embodiment.

FIG. 7 is a flow diagram of a process that may be performed by the IED of FIG. 2 to automatically associate current measurements from WCSs with voltages, in accordance with an embodiment.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Electric power delivery systems include equipment, such as generators, power lines, transformers, and the like, to provide electrical energy from a source to one or more loads. Various intelligent electronic devices (IEDs) may be used in monitoring, protection, and control of the power delivery system. For example, to perform protection and control operations, the IED may receive voltage measurements and current measurements of a power line.

The wiring for sensors used by IEDs to monitor the power lines may be costly and increase the complexity of installation. To reduce these costs, wireless current sensors (WCSs) may be used to monitor current on the power line. These WCSs may provide current magnitude and phase measurements to the IED to allow the IED to make control decisions. Further, the WCS may be connected to the power line without any power or data connections to the IED and may be powered by current through the power line. To make control decisions and protection decisions based on voltage and current, the current measurements obtained by the WCS may be associated with the voltage measurements obtained on the same phase (i.e., the same conductor).

Operators may attach a WCS on a phase, trigger an event on the phase to capture an oscillography, and determine whether the WCS is associated with the correct voltage of the phase. If the WCS is not associated with the correct voltage, the WCS may be removed from the phase and tried on another phase. This process may be repeated until a phase that corresponds to (e.g., matches with) the voltage is found.

However, repeatedly removing and attaching WCSs on different phases to find the correct associations of voltage and current may be tedious and time consuming. Further, if the operator does not know the phase shift between the voltages and currents, then there is a chance that the WCSs are installed on the incorrect phase. Associating the current with the incorrect voltage may lead to undesirable control/switching operations and incorrect metering data.

As explained below, the current measurements of WCSs may be automatically associated with voltages of the same phase of the power system. For example, a first WCS may be installed on a first phase with a voltage sensor. The IED may determine the phase shift between the voltage and current and use the phase shift as a reference. The operator may install a second WCS on a second phase. The TED may automatically associate the second WCS with the second phase based on the phase shift from the first phase. By following an expected installation process and by automatically associating the voltages and with the correct WCS using the expected installation process, repeated swapping of WCSs during the installation process may be reduced or eliminated.

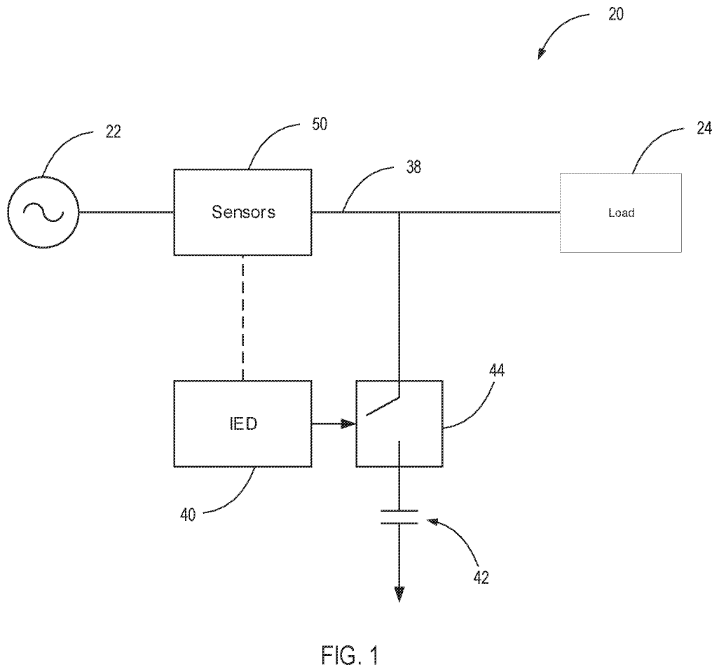

FIG. 1 illustrates a one-line diagram of an embodiment of an electric power delivery system 20, which may have various electric transmission lines, electric distribution lines, current transformers, buses, switches, circuit breakers, reclosers, transformers, autotransformers, tap changers, voltage regulators, capacitor banks, generators, motors, pumps, compressors, valves, and a variety of other types of monitored equipment. For illustrative purposes, the electric power delivery system 20 includes a power source 22 that provides power to a load 24. The electric power delivery system 20 includes a power line 38 that is communicatively coupled between the power source 22 and the load 24 to deliver power from the power sources 22 to the load 24.

The electric power delivery system 20 may be monitored, controlled, and/or protected by an intelligent electronic device (IED) In the illustrated embodiment, the electric power delivery system 20 includes an IED 40, such as a capacitor bank controller (CBC). A CBC may control a capacitor bank 42 by sending signals to a switch 44 to electrically connect or disconnect the capacitor bank 42 from the power line 38. While a CBC is used as an example in the illustrated embodiments, note that the methods and systems described below may be perform with WCSs in conjunction with any suitable IED, for example, remote terminal units, differential relays, distance relays, directional relays, feeder relays, overcurrent relays, voltage regulator controls, voltage relays, breaker failure relays, generator relays, motor relays, automation controllers, bay controls, meters, recloser controls, communication processors, computing platforms, programmable logic controllers (PLCs), programmable automation controllers, among others. Further, while illustrated as a single capacitor, note that several capacitors may be used and the particular size of the capacitor bank may depend on the application.

The IED 40 may obtain electric power system information using one or more sensors 50. For example, potential transformers (PTs) may be electrically connected from the power line to the IED 40 to provide the IED 40 with a voltage signal proportional to the voltage on the power line 38. Further, current transformers (CTs) may be connected from the power line 38 to the IED 40 to obtain a current signal proportional to current on the power line 38.

As mentioned above, wiring CTs from the power line to the IED 40 may be complicated, time consuming, and costly. To simplify this process, WCSs may be connected to the power line to provide wireless current measurements to the IED 40. The WCSs may be connected to the power line 38 without any communication or power conductors routed to the IED 40 by harvesting power from the power line 38 and may provide wireless signals indicating current measurements to the IED 40. Although illustrated in single-line form for purposes of simplicity, the electric power delivery system 20 may be a multi-phase system, such as a three-phase electric power delivery system.

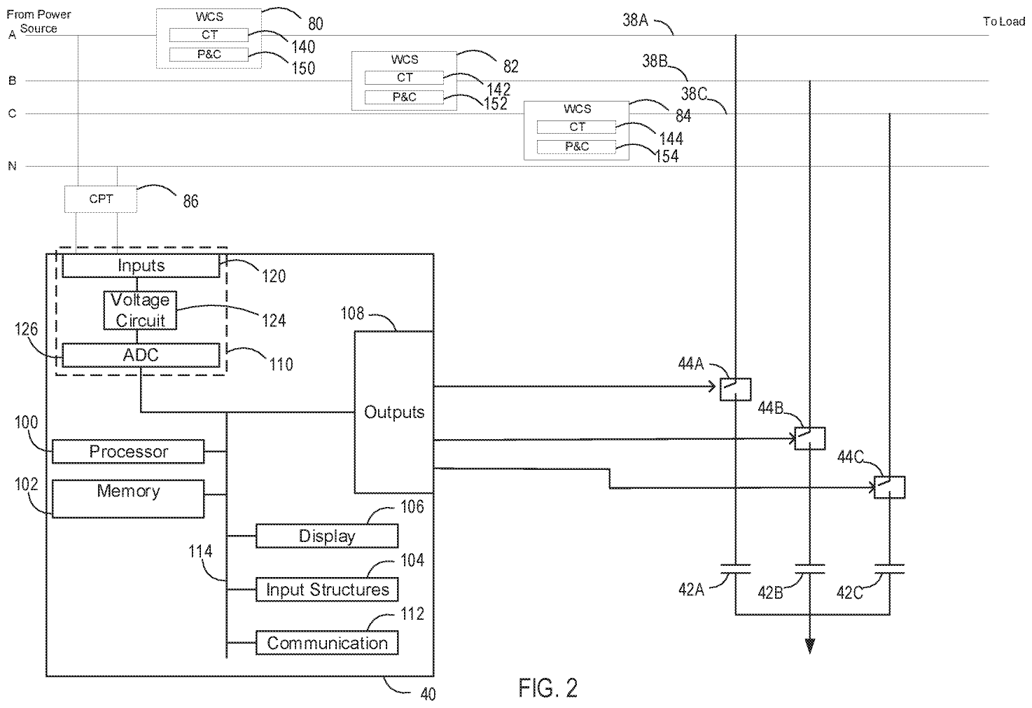

FIG. 2 is an embodiment of an example of a three-phase electric power delivery system with an IED 40 that uses WCSs 80, 82, and 84 to monitor current on each phase of a power line 38A-C. In the illustrated example, the IED 40 controls electrical connection and disconnection of the capacitor bank 42A-C to the phases of the power line 38A-C based in part on current measurements and voltage measurements to improve the power quality of the power system. While the illustrated example is of a CBC, the IED may be, for example, a relay that uses current measurements associated with voltage measurements to detect events (e.g., fault events) and to trip a circuit breaker upon detection of such events. The WCSs 80, 82, and 84 may communicate wireless current measurements, such as current magnitude and current phase, of each phase to the IED 40. The IED 40 may include a transceiver that receives the wireless current sensor measurements from the wireless current sensors 80, 82, and 84.

The IED 40 may perform control operations of the capacitor bank 42 by sending control signals to the one or more switching devices 44A-C of the capacitor bank based on voltage measurements from one or more voltage sensing devices (e.g., voltage sensors, potential transformers (PTs), control power transformers (CPTs) 86, etc.) and wireless current measurements from wireless current sensors 80, 82, and 84. As illustrated, the IED 40 may send individual control signals (e.g., open or close signals) to each of the switches 44A-C to perform single pole switching in a current control scheme. For example, the IED 40 may individually control switch 44A based on the current from the A-phase the wireless current sensor 80 and the PT 86, control switch 44B based on the current of the B-phase from the wireless current sensor 82 and a synthesized voltage of the B-phase, and control switch 44C based on the current of the C-phase from the wireless current sensor 84 and a synthesized voltage of the C-phase. In the illustrated example, the voltages for B-phase and C-phase may be synthesized as being 120 degrees offset from the voltage measurements of the A-phase. In other embodiments, additional PTs may be connected to the B-phase and C-phase.

The IED 40 may determine a power factor of the B-phase and C-phase based on the zero crossings from the wireless current measurements and an estimated zero crossing derived from the voltage measurements of the A-phase (e.g., estimated to be 120 degrees offset from voltage measurements of the A-phase). Based on the estimated power factor of the B-phase and/or C-phase, the IED 40 may send close signal(s) to switches 44B and 44C to increase the capacitance via the capacitor bank thereby improving the power factor of the B-phase and/or C-phase. While power factor is given as an example, the IED 40 may perform VAR control of the capacitor bank 42 using estimated voltages of the B-phase and C-phase based on the measured voltage of the A-phase to control the switches 44A-C individually. In some embodiments, the IED 40 may perform control operations according to a first control scheme (e.g., power factor control scheme) on a first phase and perform control operations according to on other phases (e.g., the B-phase and C-phase) according to a second control scheme (e.g., VAR control).

The IED 40 includes a processor 100, a computer-readable storage medium 102, input structures 104, a display 106, output circuitry 108, sensor circuitry 110, and communication circuitry 112. The IED 40 may include one or more bus(es) 114 connecting the processor 100 or processing unit(s) to the computer-readable storage medium 102, the input structures 104, the display 106, the output circuitry 108, the sensor circuitry 110, and/or the communication circuitry 112. The computer-readable storage medium 102 may be embodied as memory, such as random access memory (RAM), read only memory (ROM), or a combination thereof, and may include or interface with software, hardware, or firmware modules for implementing various portions of the systems and methods described herein. The computer-readable storage medium 102 may be the repository of one or more modules and/or executable instructions configured to implement any of the processes described herein.

The processor 100 may process inputs received via the sensor circuitry 110 and the communication circuitry 112. The processor 100 may operate using any number of processing rates and architectures. The processor 100 may be configured to perform various algorithms and calculations described herein using computer executable instructions stored on computer-readable storage medium 102. The processor 100 may be embodied as a microprocessor. In certain embodiments, the processor 100 and/or the computer-readable storage medium 102 may be embodied as discrete electrical components, a general purpose integrated circuit, one or more Application Specific Integrated Circuits (“ASICs”), a Field Programmable Gate Array (“FPGA”), and/or other programmable logic devices. The processor 100 and/or the computer-readable storage medium 102 may be referred to generally as processing circuitry.

As illustrated, the sensor circuitry 110 may include, for example, input pins 120 or connectors that receive voltage signal(s) from one or more voltage sensing devices (e.g., PTs 86). The sensor circuitry 110 may transform the voltage signals using an internal voltage circuit 124 to a level that may be measured (e.g., via internal transformers), and sample the signals using, for example, A/D converter(s) 126 to produce digital signals representative of measured voltage on the power line 38. The A/D converter 126 may be connected to the processor 100 by way of the bus 114, through which digitized representations of voltage signals may be transmitted to the processor 100.

The communication circuitry 112 may include communication ports, such as ethernet and serial ports. In some embodiments, the IED 40 may remotely control switches of the capacitor banks using by communicating using the ethernet or serial ports. Further, the communication circuitry 112 may include a wireless transceiver to communicate with one or more electronic devices, such as the wireless current sensors 80, 82, and 84. The IED 40 may include a display screen 106 that displays information to notify an operator of operating parameters of the electric power delivery system 20, such as current measurements, voltage measurements, capacitor bank status, power flow direction, etc. The input structures 104 may include buttons, controls, universal serial bus (USB) ports, or the like, to allow a user to provide input settings to the IED 40. In some embodiments, the display 106 may be a touchscreen display.

The WCSs 80, 82, and 84 may include current transformer windings 140, 142, and 144 and processing and communication circuitry 150, 152, and 154. The current transformer windings 140, 142, and 144 may detect current proportional to the current on the power line 38 to allow for monitoring of the power line 38. The processing and communication circuitry 150, 152, and 154 may include any suitable electrical components (e.g., processor, memory, etc.) to communicate current measurements obtained from the windings 140, 142, and 144 to the IED 40. For example, the processing and communication circuitry 150, 152, and 154 may include a transceiver configured to send wireless signals to the transceiver of the IED 40 to communicate current measurements of the phases of the power line 38A-C. The wireless current sensors 80, 82, and 84 may be line-powered and include power harvesting circuitry (e.g., additional CT windings) that harvests power from the power line to allow the wireless current sensors 80, 82, and 84 to perform current measurements and to communicate with the CBC 40.

The WCSs 80, 82, and 84 may communicate current magnitude and/or phase measurements to the IED 40. In some embodiments, the wireless current sensors 80, 82, and 84 may communicate zero-crossing information. For example, when current flow changes from positive to negative or negative to positive, the wireless current sensor 80, 82, and 84 may send a signal indicating the time at which the zero-crossing occurred. Further, processor 100 perform VAR or power factor control by controlling the switching device(s) 44A-C based on the current measurements and voltage measurements.

The output circuitry 108 may include one or more output pins or connectors that electrically connect the IED 40 to a control or protection device. For example, with respect to CBCs, the IED 40 may be connected to the switching device(s) 44A-C to allow the processor 100 to send control signals to the switching device(s) 44A-C to control connection or disconnection of the capacitor bank 42 to the power line 38. As illustrated, the CBC 40 has output connectors that connect switches 44A-C on each phase of the power line 38A-C. The switching device 44 may be any suitable switching device or combination of devices that connect or disconnect the capacitor bank 42, such as metal-oxide-semiconductor field-effect transistors (MOSFETs), relays, switches, etc. Further, the switching devices 44A-C are illustrated as switches that perform individual switching to control each of the phases individually. In other embodiments, the switching device 44 may be a ganged switching device that controls the phases together based on a combination of the voltage and current measurements of different phases.

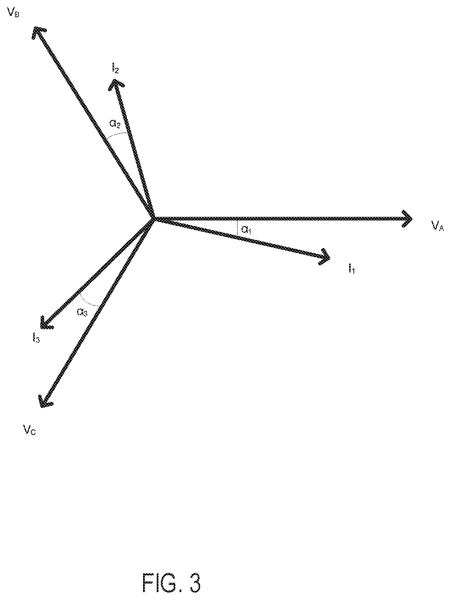

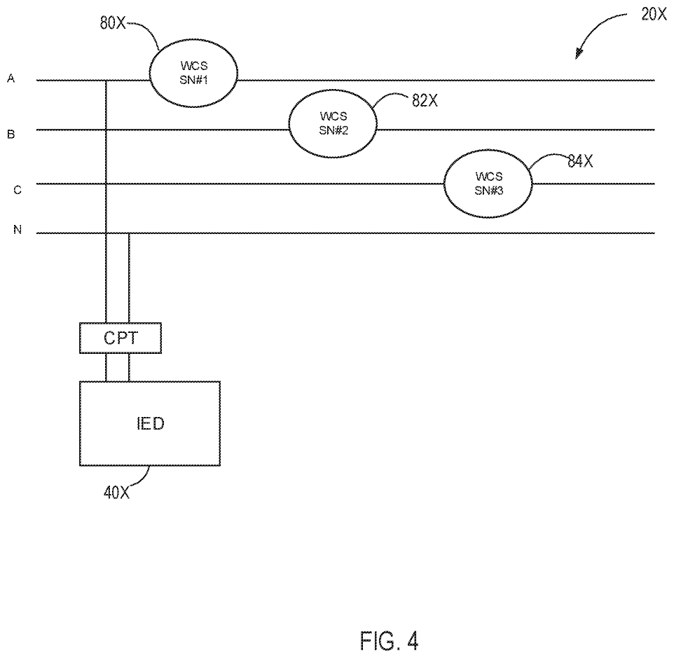

FIG. 3 is a phasor diagram of the voltages and currents of each of the phases A-C from FIG. 2. The voltage VA may be the voltage measurement obtained via the voltage sensing device (e.g., PT 86). The B-phase voltage VB may be a synthesized voltage at 120 degrees offset from the A-phase, and the C-phase voltage may be −120 degrees offset from the A-phase. While the illustrated embodiment of FIG. 2 includes synthesized voltages for the B-phase and the C-phase, as described below with respect to FIG. 4, the voltages may be measured from respective PTs on the B-phase and/or C-phase.

The phase shift between the voltage and current may be used in calculating the PF and kVAR values that are used by the IED 40 to control the capacitor bank 42. For example, in PF control, the IED 40 may connect the capacitor bank 42 when inductive loads are connected to the power line 38 to improve the PF, thereby improving the quality of power delivered to the loads. Thus, to obtain accurate PF and kVAR values, the current measurements are associated with the corresponding voltage measurements of the particular phase of the power line.

To install the WCS, a hot stick may be used to enclose two halves of the WCS around the conductor to allow the CT windings of the WCS to harvest energy and to obtain current samples from the conductor. Upon connecting the WCS, the WCS may communicate current measurements to the IED. During installation, the current measurements of a WCS may be compared with voltage measurements of a voltage sensing device (e.g., PT) to associate the current measurements with the correct voltage measurements of the corresponding voltage sensing device on the same phase. For example, an event may be captured using oscillography to check that the correct association is made.

However, as mentioned above, repeatedly removing and re-attaching WCSs on different conductors to find the correct associations of voltage and current may be tedious and time consuming. Additionally, the phases of the power line 38A-C may be transposed throughout the power line 38 for various reasons, such as to improve balance between the phases. Further, if the operator does not know the phase shift between the voltages and currents, then there is a chance that the WCSs are installed on the incorrect conductor. As described below, various predetermined methods may be used to install the WCSs to allow for automatic association of the voltage of each phase with the corresponding current measurements from the WCS connected to that phase.

FIG. 4 is a block diagram of an example of an IED 40X that uses a first method for associating wireless current measurements with corresponding voltages of the same phase. In the first method, each WCS 80X, 82X, and 84X is given a unique serial number (e.g., 8 digits). While in the first method the unique serial number may be a universally unique number with respect to any other manufactured WCS, in other methods described below, a unique number may be given with respect to the other WCSs in a set installed on a particular line. An operator installs a first WCS 80X on the conductor that has the voltage sensing device (e.g., PT 86, voltage sensor, etc.) for single-phase sensing. The first WCS 80X may establish communication with the IED 40X. The first WCS 80X may send current measurements to the IED 40X. For example, the first WCS 80X may send a current measurement indicating the time at which a zero-crossing occurred. The processor 100 may obtain a voltage measurement indicating the time at which a zero-crossing of voltage occurred. Then, the IED 40X may determine the phase shift between current measurements from the first WCS 80X and the voltage measurements from the voltage sensing device. For example, the IED 40X may compare the time at which a zero-crossing of voltage occurred to the zero-crossing of current to determine the phase shift between current and voltage of the first phase. The operator may then install the remaining two WCSs 82X and 84X on the remaining two phases. The IED 40X may use the determined phase shift to associate the two remaining WCSs with the corresponding voltages. Referring to FIG. 3, the IED 40X may associate current measurements I₂ with the synthesized or measured voltage V_{B} due to I₂ having a similar phase shift (e.g., within 1 degree, 2 degrees, 5 degrees, 10 degrees, 20 degrees, etc.) as the phase shift of the first phase. The IED 40X may then associate the remaining current measurements I₃ with the synthesized or measured voltage V_{C} of the remaining phase. Further, the IED 40X may ensure that the correct associations have been established by comparing the phase shift between the current measurements from the third WCS 84X with the synthesized voltages or measured voltages V_{C}. The IED 40X may provide a notification, on the display 106, to the operator indicating whether correct associations were established. The IED 40X may then use each of the phase differences between the voltages and the associated currents for PF control or kVAR control calculations and operations.

In single phase voltage and three-phase current sensing systems, the first WCS 80X may be installed on the same conductor as the voltage sensor (e.g., PT 86). By using the predetermined installation order in which the first WCS 80X is initially installed on the phase of the power line having a voltage sensing device (e.g., PT 86), current I₁ may be determined to be associated with the A-phase. Upon associating the A-phase current of the first WCS 80X with the A-phase voltage of the voltage sensor (e.g., PT 86), the IED 40X may determine the phase shift cu as being the difference between the A-phase voltage and the A-phase current to use as a reference phase shift. The unique serial number may be communicated with the current measurements from the WCS 80X to the IED 40X to allow the IED 40X to make control decisions using the correct association between the current measurements and voltage measurements.

The second WCS 82X may be installed following the installation of the first WCS 80X. The second WCS 82X may establish communication with the IED 40X. The IED 40X may determine which phase the second WCS 82X is associated with based in part on the phase shift between the A-phase voltage and the A-phase current. For example, the phase shift α₂ between the second WCS 82X and the associated voltage may be estimated to be approximately the same (e.g., within 1 degree, 2 degrees, 5 degrees, or 10 degrees, etc.) as the phase shift between the A-phase voltage and current. The third WCS 84X may then be installed and associated with the remaining phase voltage using the phase shift α₁. Note that any suitable method and protocol of wireless communication between the WCSs 80X, 82X, and 84X may be used. Following installation, the WCSs 80X, 82X, and 84X may continue to communicate the unique identifier to allow the IED 40X to distinguish current measurements from the WCSs 80X, 82X, and 84X.

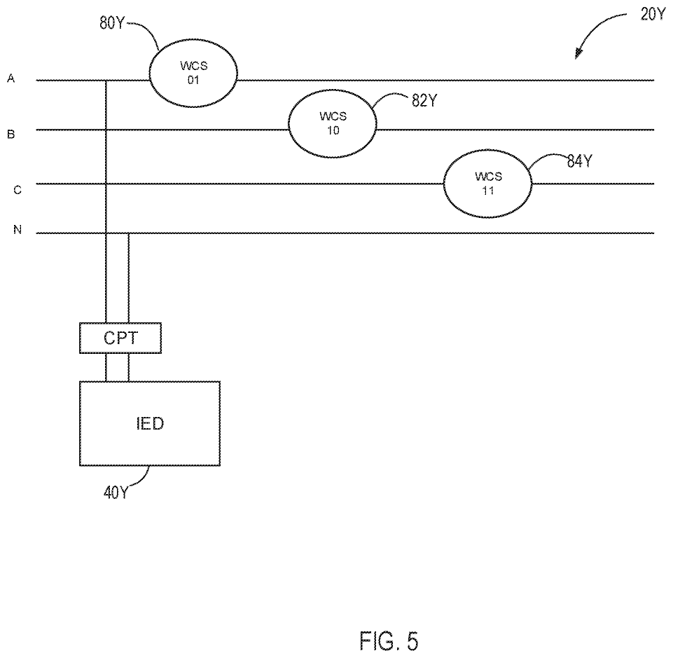

FIG. 5 is a block diagram of another embodiment of an IED 40Y that uses a second method for associating wireless current measurements from WCSs 80Y, 82Y, and 84Y to corresponding voltage measurements using communication identifiers to identify each of the WCSs. In this implementation, the WCSs may store a number (e.g., two binary digits) in memory to identify the WCS from the remaining WCSs. Similarly, in this method, a first WCS 80Y may be installed on the phase with the CPT or voltage sensor initially. The IED 40Y may determine the phase shift between voltage and current and use this phase shift as a reference, as described with FIG. 4.

An operator may then install the remaining WCSs 82Y and 84Y. Each of the WCSs 80Y, 82Y, and 84Y may retrieve the number from memory and may send the stored number with each of the current measurements to allow the IED 40Y to associate the current measurements with the correct WCS 80Y, 82Y, and 84Y.

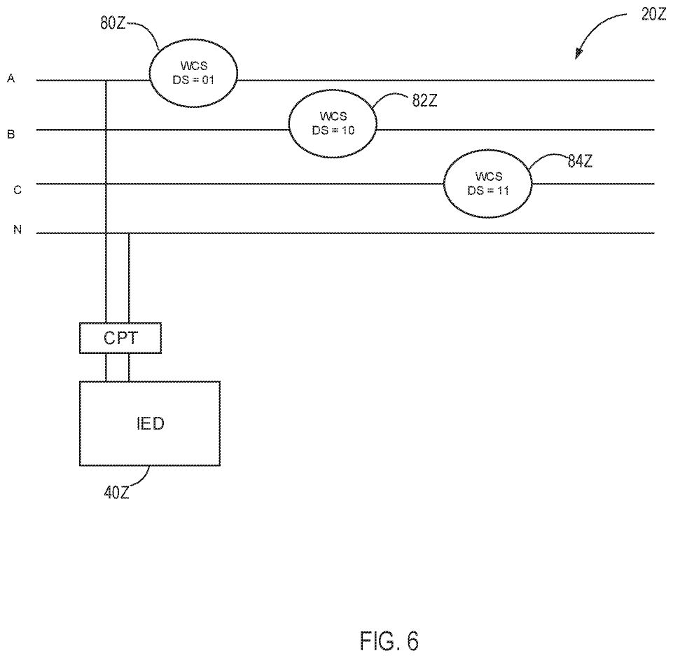

FIG. 6 is a block diagram of another embodiment of an IED 40Z that uses a third method for associating wireless current measurements from WCSs to corresponding voltage measurements of the same phase. The third method may include physical input devices on each WCS, such as dual in-line package (DIP) switches, that are used to identify a WCS. For example, each WCS may include two or more DIP switches. An operator may set the first WCS 80 to have a DIP switch value of 1. For a three-phase electric power delivery system, the DIP switches of each of the WCSs may be set to 1 (01), 2 (10), and 3 (11) for to for each of the phases. In this example, the first WCS with a DIP switch value of 1 may be installed on the phase of the power line having the voltage sensing device (e.g., voltage sensor or PT). The first WCS 80Z may communicate the DIP switch value to the IED 40Z to allow the current measurements to be associated with the first WCS 80Z. The process may continue similar to the processes described above with respect to FIGS. 4 and 5.

While the process of FIG. 6 is described using two DIP switches, a single DIP switch may be used to identify the WCS connected to the same phase as the voltage sensing device. For example, an operator may set the DIP switch that is connected to the same phase as the voltage sensing device to 1 and set the other two WCSs for the remaining phases to be zero. As such, the IED 40Z may determine a phase shift between the current measurements from the WCS with a DIP switch value of 1 to the voltage measurements of the voltage sensing device. The determined phase shift may be used as a reference phase shift for the remaining two phases with DIP switch values of 0.

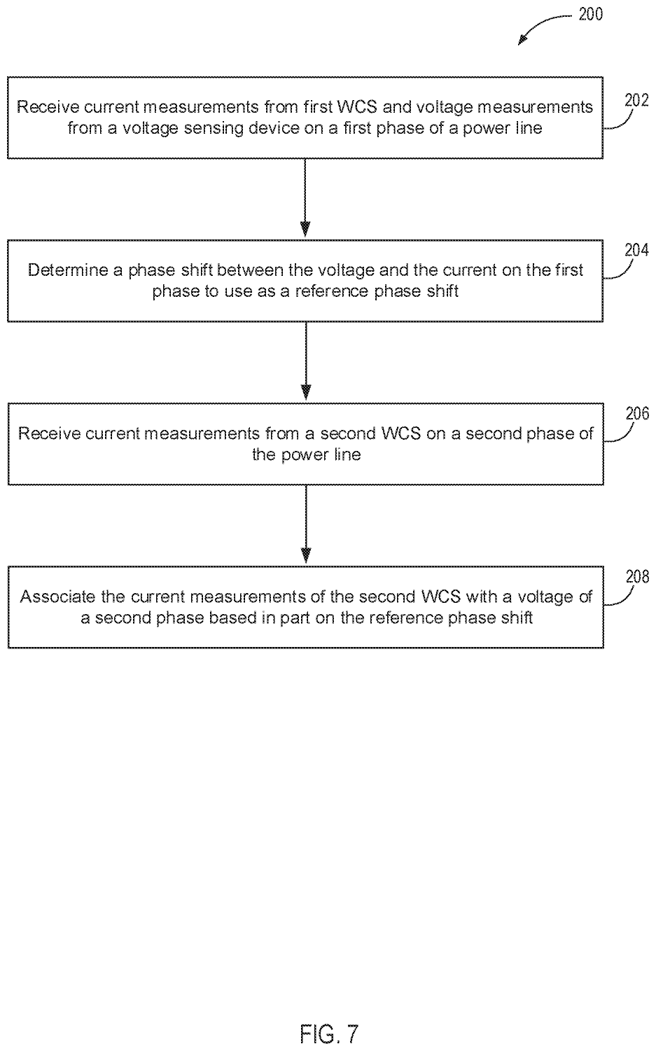

FIG. 7 is an embodiment of a flow diagram of a process 200 to associate each WCS with corresponding voltages of the same phase. In some embodiments, the process 200 may begin with setting inserting the identifiers described above with respect to FIGS. 4-6. For example, the DIP switches may be set to the desired identifier of each WCS. Further, the memory of the WCSs may be updated to include an identifier. A first WCS may be installed on a first phase of the power line. For example, the first WCS may be installed on the phase that includes a voltage sensor or PT. The IED 40 may establish communication with the first WCS 80.

The processor 100 may receive current measurements from the first WCS 80 and voltage measurements from the voltage sensing device (e.g., voltage sensor or PT) (block 202). For example, the processor 100 may receive zero-crossing times of current, magnitude and phase measurements, maximum amplitude times, etc. The processor 100 may determine a phase shift between the current and the voltage on the first phase based on the current measurements and the voltage measurements (block 204). For example, the processor 100 may compare the time at which a zero-crossing of current occurred to the time at which a zero-crossing of voltage occurred to determine the phase shift between the current and the voltage on the first phase. The processor 100 may then use the phase shift of the first phase as a reference phase shift to be used in conjunction with the remaining two phases to allow for automatically associating the remaining phases.

The processor 100 may then receive current measurements from a second WCS 82 (block 206) on a second phase of the power line 38. In some embodiments, the IED 40 may have a single-phase voltage sensing device or a set of three-phase voltage sensing devices (e.g., voltage sensors or PTs connected to each phase individually). If the IED 40 has a single voltage sensing device, the IED 40 may generate synthetic voltages based on the voltage sensing device of the first phase. If the IED 40 has a set of three-phase voltage sensing devices, the IED 40 may use the measured voltages. The IED 40 may associate the second WCS 82 with the voltage of the second phase based in part on the reference phase shift. The IED 40 may then subsequently associate the third WCS 84 with the voltage of the third phase based on the reference phase shift.

The IED 40 may perform one or more control actions or protective actions based on the associated current measurements with the corresponding voltage measurements. For example, a relay may send a signal to a circuit breaker based on the voltages and currents of the power delivery system. Alternatively, as in some of the examples above, a CBC may send a signal to open or close a switching device to control connection or disconnection of a capacitor bank based on the current measurements and the associated voltage measurements. While these are given as examples, any suitable IED 40 may be used.

While the examples used above referred to the first WCS 80 being installed on the A-phase, this was meant to be used for simplicity, and the first WCS 80 may be installed on whichever phase includes a voltage sensor (e.g., PT 86).

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An intelligent electronic device (IED), comprising:
communication circuitry configured to communicate with a first wireless current sensor (WCS) and a second WCS;
memory; and
a processor operatively coupled to the memory, wherein the processor is configured to:
receive a first current measurement from the first WCS on a first phase of the power line;
receive a first voltage quantity from a voltage sensing device on the first phase of the power line;
determine a phase shift between the first voltage quantity and the first current measurement to use as a reference phase shift;
receive a second current measurement from the second WCS on a second phase of the power line; and
associate the second WCS with a second voltage quantity based at least in part on the reference phase shift.

2. The IED of claim 1, wherein the processor is configured to:
associate a third current measurement of a third WCS with a third voltage quantity based at least in part on the reference phase shift.

4. The IED of claim 1, wherein the processor is configured to:
determine a second phase shift between the second WCS and the second voltage quantity.

5. The IED of claim 4, wherein the processor is configured to perform a control operation based at least in part on the first phase shift and the second phase shift.

6. The TED of claim 1, wherein the voltage sensing device comprises a voltage sensor or a potential transformer.

7. The TED of claim 1, wherein the first current measurement comprises a first current phase measurement and the first voltage quantity comprises a first voltage phase measurement, wherein the processor is configured to calculate the phase shift based on the first current phase measurement and the first voltage phase measurement.

8. The TED of claim 7, wherein the first current measurement comprises a first current zero crossing and the first voltage quantity comprises a first voltage zero crossing, wherein the phase shift is determined based on the time difference between the first current zero crossing and the first voltage zero crossing.

9. The TED of claim 1, wherein the TED is a capacitor bank controller (CBC).

10. A tangible, non-transitory, computer-readable medium comprising instructions that, when executed by a processor of an intelligent electronic device (IED), cause the processor to:
receive a first current measurement from the first WCS on a first phase of a power line in an electric power delivery system;
receive a first voltage quantity from a voltage sensing device on the first phase of the power line;
determine a phase shift between the first voltage quantity and the first current measurement to use as a reference phase shift;
receive a second current measurement from the second WCS on a second phase of the power line; and
associate the second WCS with a second voltage quantity based at least in part on the reference phase shift.

11. The non-transitory computer-readable medium of claim 10, comprising instructions that, when executed by a processor, cause the processor to perform an action to protect or control operation of the electric power delivery system based at least in part on subsequent current measurements and the associated voltage measurements.

12. The non-transitory computer-readable medium of claim 10, comprising instructions that, when executed by a processor, cause the processor to associate the first voltage quantity with the first current measurement from the first WCS based on an expected predetermined order of installation of WCSs in which the first WCS is installed on the first phase with the voltage sensing device.

13. The non-transitory, computer-readable medium of claim 12, wherein the expected predetermined order of installation comprises the second WCS being installed on the second phase of the power line subsequent to the first WCS installation.

14. The non-transitory computer-readable medium of claim 10, comprising instructions that, when executed by a processor, cause the processor to receive a unique identifier from the first WCS in conjunction with the first current measurement to associate subsequent current measurements of the first phase with the first WCS.

15. A method, comprising:
attaching a first wireless current sensor (WCS) to a first phase of a power line of an electric power delivery system, wherein a voltage sensing device is operably connected to the first phase; and
attaching a second WCS to a second phase of the power line following attachment of the first WCS to allow an TED of the electric power delivery system to associate a voltage of the second phase with the second WCS based at least in part on a reference phase shift between a current measurement of the first WCS and a voltage measurement of the voltage sensing device.

16. The method of claim 15, wherein the second WCS is attached to the second phase without having a voltage sensing device attached to the second phase.

17. The method of claim 15, comprising attaching a third WCS to a third phase of the power line following attachment of the second WCS to allow the IED to associate a voltage quantity of the third phase with the third WCS.

18. The method of claim 17, comprising setting a DIP switch on the second WCS to be a first value, and setting a DIP switch on the third WCS to be a second value, different from the first value, to allow the IED to identify current measurements from the second WCS and the third WCS.

19. The method of claim 17, comprising inserting, into memory of the first WCS, the second WCS, and the third WCS, a unique identifier to identify each of the first WCS, the second WCS, and the third WCS.

20. The method of claim 15, comprising:
inputting, into the IED, a first unique identifier of the first WCS; and
inputting, into the IED, a second unique identifier of the second WCS, different from the first unique identifier.
